(19) United States
(12) Patent Application Publication
(10) Pub. No.: US 2012/0298302 A1
(43) Pub. Date: Nov. 29, 2012

(54) VACUUM PLASMA PPROCESSING CHAMBER WITH A WAFER CHUCK FACING DOWNWARD ABOVE THE PLASMA

(76) Inventors: Yaomin Xia, Normal, IL (US); Shang-Fen Ren, Normal, IL (US); Benxin Xia, Saratoga, CA (US)

(21) Appl. No.: 13/470,318

(22) Filed: May 13, 2012

Related U.S. Application Data
(60) Provisional application No. 61/488,794, filed on May 23, 2011.

(51) Int. Cl. H01L 21/3065; B05B 1/18

(52) U.S. Cl. 156/345.34; 156/345.51; 156/345.44; 156/345.37

(57) ABSTRACT

A process plasma chamber for processing a wafer may include a chamber body for processing the wafer, a wafer chuck for positioning the wafer within the chamber body and a plasma body being generated by RF power in the chamber body. The wafer chuck may position the wafer downwards and above the plasma body. The chamber body may include a showerhead positioned below the plasma body. The chamber body may include a first top electrode for receiving RF power. The chamber body may include a second top electrode for receiving RF power.

### PRIORITY

The present invention claims priority under 35 USC section 119 based on a provisional application Ser. No. 61/488, 794 which was filed on May 23, 2011.

### FIELD OF THE INVENTION

The present disclosure generally relates to equipment and methods for manufacturing silicon wafers for semiconductor and related applications and more particularly to an apparatus for forming a wafer from the bottom surface.

### BACKGROUND

Silicon wafers are manufactured into semiconductor products such as integrated circuits or photovoltaic cells through a series of manufacturing steps that involves depositing or etching material on the silicon wafer. In current manufacturing process, many of these manufacturing steps are carried out in a chamber called the vacuum plasma processing chamber. Inside the vacuum plasma processing chamber, a wafer chuck secures the silicon wafer during the manufacturing steps.

The yield of semiconductor products such as integrated circuits is affected by the rate which the silicon wafers have to be scrapped due to a manufacturing defect formed during the manufacturing process. One of the main causes of the manufacturing defect is foreign particles being deposited on the wafer during the manufacturing process. To reduce the cost of products by reducing the number of manufacturing defects, the semiconductor manufacturing is performed inside clean rooms and inside a vacuum chamber to minimize such particles causing a defect.

In prior art semiconductor manufacturing equipment, the vacuum plasma processing chamber contains a wafer chuck position at the bottom of the chamber. The chuck holds up the silicon wafer from below, and the silicon wafer faces up towards the plasma body so the wafer may be etched by the plasma. Due to gravity, dust and wafer particles from the etching process may fall and deposit onto the wafer, resulting in a defect. In today's deep-submicron process nodes, even a small deposit may result in a major defect and render the entire die to be useless. The elimination of these defects may be an important factor affecting silicon processing yield especially in processes of 90 nm and below. U.S. Pat. No. 7,682,483 (Incorporated by reference in its entirety) discloses a vacuum processing chamber and method of using a vacuum processing chamber and includes a chamber defined by a chamber body, and wherein the chamber body defines an internal cavity; first and second electrodes are mounted in the internal cavity as defined by the chamber body; an RF generator is provided, and which produces single or multiple frequencies and which is electrically coupled to at least one of the first or second electrodes, and which are operable, when energized, to produce a plasma within the internal cavity of the chamber body; and an adjustable component borne by the chamber body, and which is fabricated, at least in part, from a dielectric material, and which selectively adjusts the equivalent dielectric constant which exists between the chamber body and the first electrode.

### SUMMARY

A process plasma chamber for processing a wafer may include a chamber body for processing the wafer, a wafer chuck for positioning the wafer within the chamber body and a plasma body being generated by the chamber body.

The wafer chuck may position the wafer downwards and above the plasma body.

The chamber body may include a showerhead positioned below the plasma body.

The chamber body may include a first top electrode for receiving RF power.

The chamber body may include a second top electrode for receiving RF power.

The wafer chuck may be connected to a ceramic target. The ceramic target may include a net to hold the wafer.

The net may be connected to a high-voltage source.

The wafer chuck may include a water passageway.

The wafer chuck may include a cool gas passageway.

The chamber body may include a processing gas passageway.

The chamber body may include a vacuum passageway.

### BRIEF DESCRIPTION OF THE DRAWINGS

The invention may be understood by reference to the following description taken in conjunction with the accompanying drawings, in which, like reference numerals identify like elements, and in which:

FIG. 1 illustrates a cross-sectional diagram of a vacuum processing plasma chamber of the present invention.

### DETAILED DESCRIPTION

The present invention includes a system having vacuum plasma processing chamber 100 with a wafer chuck 101 being connected to a wafer 105 facing downwards above the plasma in the chamber.

The system including the vacuum processing plasma chamber 100 to process having a silicon wafer chuck 101 which may position the wafer 105 which may be formed silicon facing downwards above the plasma body 103. As a consequence, the wafer 105 faces down towards the plasma body. In the etching process, the wafer 105 that is facing down is etched by the plasma body 103 while being held above the plasma body 103. Accordingly, dust and wafer particles produced from the etching process will fall down towards the plasma body 103, away from the wafer 105. Thus, the defect rate of the semiconductor manufacturing process can be greatly reduced. This in turn will greatly reduce the cost of manufacturing good integrated circuit dies.

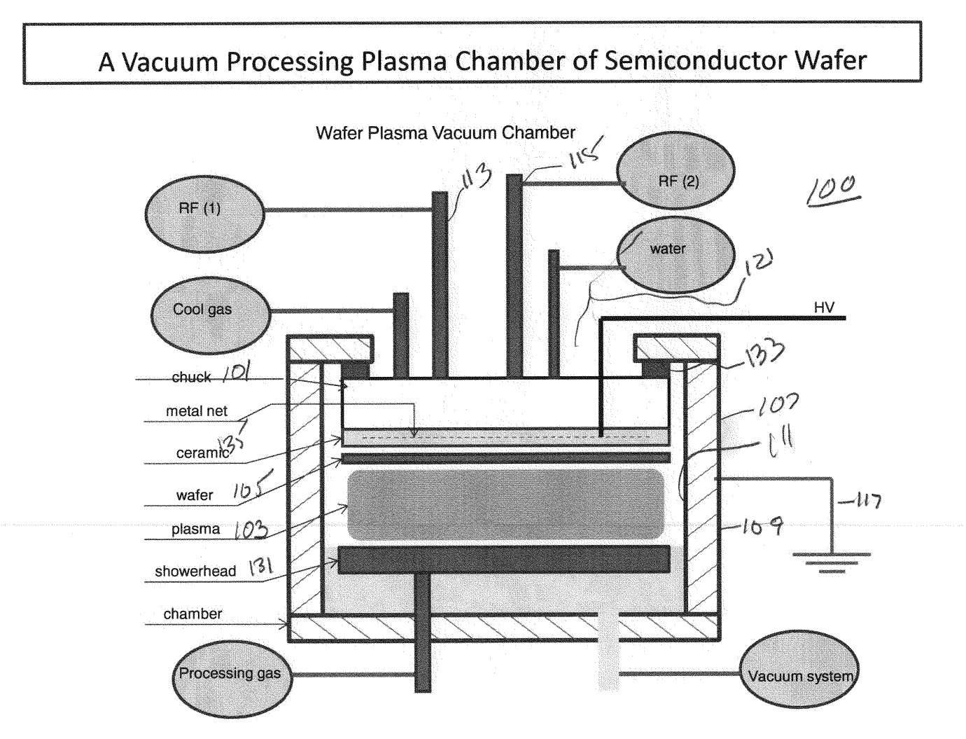

FIG. 1 illustrates a cross-sectional view of the vacuum processing chamber which is generally indicated by the numeral 100, and which is defined, in part, by a chamber body 107. The chamber body 107 may include an inside facing surface 111 which may extend around the inner periphery of the chamber body 107 and may extend across the internal top and bottom of the chamber body 107, and an opposing outside facing surface 109 which may extend around the outer periphery of the chamber body 107 and may extend across the external top and bottom of the chamber body 107. The vacuum processing chamber 100 may include a first top electrode 113 to provide a first radiofrequency (RF) electrical signal from a first electrical generator and a second top electrode 115 to provide a second radiofrequency (RF) electrical signal from a second electrical generator. The chamber body 107 may be electrically grounded 117. The chamber body 107 may include a central aperture 121 which may extend through the top of the chamber body 107. An internal cavity 119 may be defined between the inside facing surface 111 of the chamber body 107, and the first top electrode 113, and the second top electrode 115 may extend into the central aperture 121 and may connect to the wafer chuck 101. In addition, a water passageway 123 to supply water to the cavity 119 and a cool gas passageway 125 to supply cool gas to the cavity 119 may extend into the central aperture 121.

FIG. 1 additionally illustrates a processing gas passageway 127 may extend through the bottom of the chamber body 107 and may connect to the showerhead 131 to supply processing gas to the showerhead 131 and illustrates a vacuum passageway 129 which may extend through the bottom of the chamber body 107 and may connect to the showerhead 131 to provide a vacuum for the cavity 119.

The gas distribution showerhead 131 for use in a semiconductor fabrication process may include a face plate having gas outlet ports in the form of elongated slots or channels. The use of elongated gas outlet ports in accordance with embodiments of the present invention substantially reduces the incidence of undesirable spotting and streaking of deposited material where the showerhead 131 is closely spaced from the wafer 105.

FIG. 1 illustrates that the chamber body 107 may include a connecting ring 133 which may connect to the top of the interior facing surface 111 and which may connect to the wafer chuck 101, and the wafer chuck 101 which may be a cylinder shaped and which may be connected to target 135 which may be formed of insulated material and may be formed from a ceramic or other appropriate material.

A net 137 which may be overlapping wires and which may be formed from conductive material such as metal may be electrically energized by a high-voltage (HV) source of electricity to hold the wafer 105 in position and may prevent the wafer 105 from being separated from the target 135, and the net 137 may be embedded within the target 135. When the RF power is applied to the target 18 under a vacuum state, the gas becomes ionized by a glow discharge so that a plasma discharge occurs as the plasma body 103. The positive-charged ions which exist in the discharge region become striking the surface of the wafer 105 by an electrical power.

The present invention reduces the defect density of silicon wafers 105 being etched by the plasma body 103 while situated above the plasma body 103 facing downwards so that deposits from the etch process and other contaminant particles, falls away from the wafer 105 because of gravity. The wafer chuck 101 may be facing downward that can hold silicon wafers above the plasma body.

The wafer chuck 101 holds the silicon wafer 105 from above facing downward above the plasma body 103 in the vacuum plasma processing chamber 100.

The wafer chuck 101 inside the vacuum plasma processing chamber 100 may not require lift pins. The vacuum plasma processing chamber 100 may include a RF power supply for the wafer chuck 101 that feeds in from the top of the chamber body 107.

The vacuum plasma processing chamber 100 may be designed with the high voltage input for the wafer chuck 101 that feeds in from the top of the chamber.

The wafer chuck 101 may secure the downward facing wafer 105 from above with high-voltage static electricity.

The high-voltage static electricity may be supplied via a metal (or other conductive) network 137 embedded in the ceramic 135 (or other non-conductive) surface of the wafer chuck 101. The high-voltage static electricity may be sent through the metal network 137, and the resultant electro-static force secures the silicon wafer 105 to the wafer chuck 101. The wafer may be attached on the surface of the wafer chuck 101 even when the wafer may be facing down. The attachment may be the result of the high voltage from the power supply that may be connected to the network 137.

The pressure of the cool gas may be substantially 20 to 30 pound/inch, so the chucking force may be much larger than cool gas pressure. The high voltage may be about 500 to 700 V/mm (here “mm” is the distance of from network 137 to chuck ceramic surface of the wafer chuck 101. For example, if the distance from network 137 to chuck ceramic surface may be substantially 3 mm, then the high voltage may be about an 1,500 to 2,000V for 8″ to 12″ wafers. Other voltages may provide similar results.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed.

1) A process plasma chamber for processing a wafer, comprising:
a chamber body for processing the wafer;
a wafer chuck for positioning the wafer within the chamber body;
a plasma body being generated by the chamber body;
wherein the wafer chuck positions the wafer downwards and above the plasma body.

2) A process plasma chamber for processing a wafer as in claim 1, wherein the chamber body includes a showerhead positioned below the plasma body.

3) A process plasma chamber for processing a wafer as in claim 1, wherein the chamber body includes a first top electrode for receiving RF power.

4) A process plasma chamber for processing a wafer as in claim 1, wherein the chamber body includes a second top electrode for receiving RF power.

5) A process plasma chamber for processing a wafer as in claim 1, wherein the wafer chuck is connected to a ceramic target.

6) A process plasma chamber for processing a wafer as in claim 5, wherein the ceramic target includes a net to hold the wafer.

7) A process plasma chamber for processing a wafer as in claim 6, wherein the method is connected to a high-voltage source.

8) A process plasma chamber for processing a wafer as in claim 1, wherein the chamber body includes a water passageway.

9) A process plasma chamber for processing a wafer as in claim 1, wherein the chamber body includes a cool gas passageway.

10) A process plasma chamber for processing a wafer as in claim 1, wherein the chamber body includes a processing gas passageway.

11) A process plasma chamber for processing a wafer as in claim 1, wherein the chamber body includes a vacuum passageway.
